(19) United States
(12) Patent Application Publication
(10) Pub. No.: US 2026/0105208 A1
(43) Pub. Date: Apr. 16, 2026

(54) Method and Apparatus for Stockpile Ore Characterization and Kinetics

(71) Applicant: FREEPORT MINERALS CORPORATION, Phoenix, AZ (US)

(72) Inventors: Eric E. Snyder, Mesa, AZ (US); Brian Njenga, Phoenix, AZ (US); Dinkar Mylaraswamy, Phoenix, AZ (US); Joshua Mory, Winston-Salem, NC (US); Joseph Zachry King, Chandler, AZ (US); Meng Zhang, Santa Clara, CA (US); Travis Gaddie, Denver, CO (US); Charles Laurin, Phoenix, AZ (US); Achal Sharma, Dwarka (IN); Jonathan Hahn, Saint Paul, MN (US)

(73) Assignee: FREEPORT MINERALS CORPORATION, Phoenix, AZ (US)

(21) Appl. No.: 18/914,699

(22) Filed: Oct. 14, 2024

(51) Int. Cl. G06F 30/17

(52) U.S. Cl. CPC G06F 30/17

(57) ABSTRACT

The method may comprise determining a geometry of a stockpile based on the haulage data, engineering drawings and material characteristics; predicting, by the one or more processors using an algorithm implementing a cellular automaton, material movements within the stockpile, based on the geometry of the stockpile, physical parameters of the material movements and emergent rules for the material movements; predicting material movements exiting the stockpile, based on the material movements within the stockpile; predicting, using a concentrator transit model, the material movements across a comminution process in a concentrator, based on material movements exiting the stockpile; and optimizing mining operations based on the knowledge of the material movements through the comminution process. A determination of the material movements may include a determination of the material characteristics of the material.

### FIELD

This disclosure generally relates to predicting the movements of ore and characterizing the ore in both the stockpile (using a stockpile model) and the concentrator through the comminution process (using a concentrator transit model), and more particularly, to optimizing mining operations based on predicting and characterizing of the ore, optimizing the usage of consumables, setting of operational parameters to increase equipment uptime and efficacy, increasing target ore recovery, reducing wasted consumables, and providing other benefits for a processing facility.

### BACKGROUND

The mining process often includes following a mine plan that may involve blasting the ore, loading the ore into trucks, hauling the ore to dump locations, dumping the ore into a crusher, reducing the ore in size, stacking the ore in an intermediate ore stockpile (IOS), then drawing the ore from the IOS into a concentrator for a comminution process. A mining company may use mine material tracking (MMT) to help track where the ore is mined, where the ore is dumped and associate the dump loads with the mineralogy from the drill (blast) holes. As such, a mining company may track the material from the mining location, through the transportation process and on the IOS.

However, after the material is dumped onto the IOS, the material may be mixed, moved and blended with other material while in the IOS and/or during the comminution process. As such, the tracking of the mineralogy through IOS and/or during the comminution process often becomes very difficult. In particular, the tracking of the material through the IOS and comminution process (e.g., crushing, grinding, milling, floatation, etc.) becomes complicated because of the crushing, mixing, blending, stacking and/or reclamation of the material in the IOS and the crushing, sorting, mixing and blending of the material during the comminution process. Therefore, a need exists to extend the tracking of the material characteristics beyond the mining steps and throughout the stockpile process and comminution process.

### SUMMARY

As set forth in FIG. 6, in various embodiments, the system may perform a method comprising determining a geometry of a stockpile based on the haulage data, engineering drawings and material characteristics (step 605); predicting, by the one or more processors using an algorithm implementing a cellular automaton, material movements within the stockpile, based on the geometry of the stockpile, physical parameters of the material movements and emergent rules for the material movements; (step 610); predicting the material movements exiting the stockpile, based on the material movements within the stockpile (step 615); predicting, using a concentrator transit model, the material movements across a comminution process in a concentrator, based on the material movements exiting the stockpile (step 620); and optimizing mining operations based on the material movements through the comminution process (step 625).

As set forth herein, in various embodiments, a determination of the material movements may include a determination of the material characteristics of the material. The predicting the material movements across the comminution process may further comprise modeling bins using the concentrator transit model. The material movements exiting the stockpile may include timing of the material exiting the stockpile and composition of the material exiting the stockpile. The concentrator may include at least one of secondary crushing, tertiary crushing or milling.

The method may further comprise optimizing fragmentation during the blast to improve the comminution process. The method may further comprise determining throughput by the blast. The method may further comprise adjusting the comminution process, based on the mineralogy entering the concentrator. The method may further comprise predicting material movements through the comminution process in the concentrator. The method may further comprise predicting material movements through the comminution process in the concentrator, based on input from sensors in components of the concentrator. The method may further comprise predicting material movements through the comminution process in the concentrator, based on input from sensors in components of the concentrator, wherein the sensors are associated with at least one of conveyors, scales or bins. The method may further comprise predicting a quantized mass element identifier associated with the stockpile through the comminution process. When a cube or block goes through comminution, the association with stockpile geometry may be lost when it leaves the stockpile, so the system may track mass, instead of blocks or cubes. The blocks may still be associated with mineralogy data (which was keyed to blocks in the stockpile) through comminution; however, the blocks may be subdivided in the process.

The predicting the material movements across a comminution process may include incorporating a configuration file of component parameters into the concentrator transit model. The predicting the material movements through the stockpile may also include incorporating a configuration file of component parameters into the blockpile (piledriver) model. The concentrator transit model may account for at least one of in-circuit blending, process survival or transit times. The predicting the material movements may include providing a real-time simulation of the material movements. The predicting the material movements across the comminution process may be based on at least one of sensor input, feeder speed, bin levels, motor speed limits, or conveyor characteristics. The predicting the material movements may be in real-time. The predicting the material movements across the comminution process may include monitoring the material entering a bin and monitoring the material leaving the bin, based on segments of the bin, conveyors feeding the bin and conveyors under the bin. The predicting the material movements across the comminution process may include monitoring the material entering a conveyor and monitoring the material leaving the conveyor, based on segments of the conveyor, throughput of the conveyor, length of the conveyor and speed of the conveyor. The method may further comprise optimizing the comminution process based on the material movements through the comminution process.

The method may further comprise determining metal recovery performance for a plan block; determining additional of the metal recovery performance by blast; determining loading data by spatial block; and predicting material characteristics based on the metal recovery performance, the loading data and the haulage data. The haulage data may be based on dump location data and dump time. The method may further comprise displaying material characteristics of the material movement over time.

### BRIEF DESCRIPTION OF THE DRAWINGS

A more complete understanding of the present disclosure may be derived by referring to the detailed description and claims when considered in connection with the Figures, wherein like reference numbers refer to similar elements throughout the Figures, and:

FIG. 1 is an exemplary stockpile showing the order of insertion and the order of extraction, in accordance with various embodiments.

FIGS. 2A-2C are three sections of an exemplary dashboard showing a material characteristics estimator for ore exiting the stockpile and for different components used in the comminution process, in accordance with various embodiments.

FIG. 3 is a graphic showing exemplary components of the concentrator, in accordance with various embodiments.

FIG. 4 is an exemplary graphic showing material being loaded into a bin and unloaded out of a bin, in accordance with various embodiments.

FIG. 5 is an exemplary graphic showing material being loaded onto the conveyor and unloaded off the conveyor, in accordance with various embodiments.

FIG. 6 is an exemplary flow chart of the stockpile model process and model process, in accordance with various embodiments.

### DETAILED DESCRIPTION

In various embodiments, the system may include one or more models or parts of models such as, for example, a stockpile model (blockpile or pile driver) and concentrator transit model (comminution model). The stockpile model may model different aspects of the stockpile. The concentrator transit model may describe different aspects of the concentrator and comminution process. The system may measure the movement of generic material in the system. The system may track the mineralogical properties of that material (specifically, using OSAs to measure Cu, Fe and Mo content). The system may predict properties like ISA, kaolinite, As, etc., which cannot be practically measured in the live stream. The system (and/or an observer operating the system) may periodically reset the state of the models based on external inputs. The system may also include periodic error correction (e.g., using a Kalman Filter) based on survey results (known as survey resets). The system as disclosed herein may include various functions, features, models, data and/or operations of a copper mine and the movement of copper. However, similar systems, components, functions, features, models, data and/or operations may be used to obtain data about any type of mine or how to improve the yield of any type of material. While this disclosure may discuss the system receiving data, reacting, adjusting, managing and the like, the disclosure also contemplates in all embodiments that the system may provide information to plant operators to allow the plant operators to receive data, react to inputs, adjust plant operations and/or proactively manage multiple processes. This may also extend to autonomous reactions to inputs in the case of a closed loop (or semi closed loop) system where adjustments, management, and the like are affected without human intervention. In that regard, the system may include closed loop control of mill operating parameters.

A stockpile model is a two-dimensional or three-dimensional representation of a stockpile based on engineering specifications. The engineering specifications may include, for example, mass, size, height, angle of repose, feeder positions, stacker positions, overlap of stockpiles and/or the like. The stockpile may be divided into blocks (e.g., blocks of uniform mass). The block mass determines the granularity of the simulation with smaller blocks increasing accuracy at the expense of computational expense. In various embodiments, the system may include adjustable granularity of simulation (e.g., 1 second, 1 minute, 1 hour, etc.). Block masses between about 10-100 tons may provide suitable accuracy, while allowing the simulation to be run in real time on commercial hardware. In various embodiments, each stockpile (or any portion thereof) may be covered by a separate stockpile model. The term stockpile may be used herein, but the system and modeling may similarly apply to a stockpile, multiple stockpiles, a leach pad, multiple leach pads, a lift, multiple lifts, a section, multiple sections, etc. and the terms may be used interchangeably. The stockpile may include different layers called lifts (e.g., 50-foot height sections). A lift may be divided into sections, wherein the section may be any shape and size. Each section may be separately irrigated and tracked. The predicting or tracking for each section may include days under leach, raffinate flow, temperature monitoring, etc. Conceptually, the middle of a lift may include more uniform rectangular sections, while the edges of the stockpile may include irregular shaped sections because the edges may not be as uniform or consistently shaped as the middle of the lift. However, based on the principle of uniformity, all mass quanta follow the same rules for movement, regardless of where the mass quanta are in the lattice (the quantized space in which the stockpile may exist).

With respect to the stockpile modeling, in various embodiments, the system may include tracking, predicting, modeling and/or simulating of the ore material through the IOS. The ore material may experience mixing, blending and/or stacking while going through the IOS, making the ore material difficult to track. Therefore, this system may provide a more accurate and granular view of the mineralogy that is received by the concentrator. Based on this more accurate view of the mineralogy, the system and/or the operations team (e.g., mineralogists) or an automated agent, may adjust the comminution process to account for the mineralogy entering the concentrator. The system may track the mineralogy by leveraging the mine material tracking (MMT) input, capturing the stockpile's geometry (e.g., surveys, engineering drawings of the IOS, locations of stackers and feeders), accounting for first principles concepts (e.g., the force of gravity, angle of repose, material flow, density, tonnage factors and/or the like), capturing pile phenomenon (e.g., pile chimneying, live zones, dead zones, the actions of bulldozers for stockpiles, auto-dozing (or virtual dozing) for stockpiles, mass purge for models and/or the like), considering physical capacities of the comminution process (e.g., crushers, bins, belts, screens and the like), receiving input from sensors on the IOS and one or more algorithms (e.g., cellular automaton, Kalman filters and/or the like) to integrate the information into a predictive simulation.

With respect to tonnage factors, the system uses a weightometer to determine a weight of the material that is dumped from the dump truck into the crusher. With respect to the known measurement errors, the Kalman filter may correct for known measurement errors and biases from the weight scales. The scales may have a built-in bias, and the scales may not be able to be re-calibrated on a regular basis, for safety and production reasons. The system may periodically survey the volume in the stockpile (e.g., by LIDAR) and convert the volume to tonnage, so the system has a more accurate inventory of the stockpile. The system may convert the volume into a weight. However, the volume may not be uniform, so the system may need to make assumptions about the volume by using density, side slopes and tonnage factors in order to obtain the volume to weight conversion. However, the system may not want to wait to obtain the results of the periodic survey. Instead, the system may also monitor the scales to determine the mass balance (mass in and mass out) of the stockpile. This mass balance analysis helps to determine what the mass should be in the pile, and the actual mass amount is often very different from the scale analysis. The system may use the Kalman filter to analyze the historical distribution of the error. Based on the historic distribution of the error, the system may implement corrections such that the survey reports are very close to the scales reporting of the mass balance. As such, the error corrections are minimized because the Kalman filter is used more often to adjust the mass. Certain parameters may control the simulation dynamics for the stockpile modeling such as, for example, IOS height, pile separation, location of primary discharge conveyors (source), location of mill feeders (sink), internal and external slope angles (angles of repose) and pile state (e.g., shrinking, growing, chimneying). In various embodiments, the system may include adjustable granularity of simulation (e.g., 1 second time resolution, 1 minute time resolution, 1 hour time resolution, 1 ton mass quanta, 10 ton mass quanta, 100 ton mass quanta, etc.). The system may develop a robust architecture that is fault tolerant, fault resistant and/or highly stable over time. In various embodiments, the system may (e.g., in real-time) adjust the simulation based on equipment status (e.g., crushers or lines being down). In various embodiments, the system may trigger the simulation based on an event (e.g., when MMT records arrive).

A stockpile may have a foundation or base that provides the support for the stockpile. The stockpile may include dead zones. The dead zones are areas of the stockpile containing material that may not exit through the one or more feeders under the influence of gravity alone, while live areas contain material that may flow into the one or more feeders under the influence of gravity. The stockpile may draw the live material into the one or more feeders, but the material at or beyond the angles of repose (e.g., in the dead zones) may not be able to be drawn toward the one or more feeders. The dead zones may be drawn into the feeder, only if the dead zones are dozed (e.g., pushed) toward the one or more feeders, so the dead zone material can move into the feeder. The simulation algorithm has the ability to conduct auto-dozing (or virtual dozing) to simulate the movement of the dead-zone material to an area where the material will flow by gravity into the feeders (e.g., toward the middle of the stockpile).

With respect to mass purge, the system experiences mass (material) build-up in one or more of the models because the ore material may be recycled, after each reiteration. In particular, a certain percentage of the ore material may be sufficiently crushed, then the remaining ore material may be re-cycled through the process again to try to further crush the remaining ore material. For example, for a block, the screen (e.g., secondary screen, tertiary screen, etc.) may determine that 60% (of the fine material) may go downstream and 40% (of the coarse material) may go back upstream to be re-cycled back into the comminution process (e.g., crushers, grinders, cyclone). The 40% of the remaining material may get further divided such that 60% of the remaining material may go downstream and 40% of the remaining material may go back upstream. A similar 60%/40% split may continue until the system gets small amounts of material from older blocks. The simulation may eventually remove (purge or prune) this small amount of material (e.g., removing dust), such that the system no longer splits this very small amount of material anymore. The stockpile model may operate in a quantized mode, where the mass packets are not subdivided in this way. The system may use quanta much smaller than 100 tons (e.g., 1-10 tons). This may eliminate the creation of infinitesimal mass sections, which purging is intended to remedy. As such, this may increase the efficiency and reduce storage requirements for the stockpile model.

The sensors on, in or around the IOS may be used to determine how much material is being extracted from the IOS and into the comminution process. In various embodiments, the system may also move a particular block down the stockpile to simulate the ore movement, and based on how the blocks are distributed above, below and around the particular block. In the past, systems would consider the blocks in a stockpile following the first in, first out principal. However, the present system takes into account the shape of the stockpile and the relative rate of material entering and leaving the pile which may lead to blocks exiting the pile in a different order. Depending on the height of the pile and the relative locations of the stackers and feeders, it may not be possible for a block to potentially reach any of the available feeders under the force of gravity. Such blocks are said to reside in the dead volume and would require the action of a dozer to be removed from the pile.

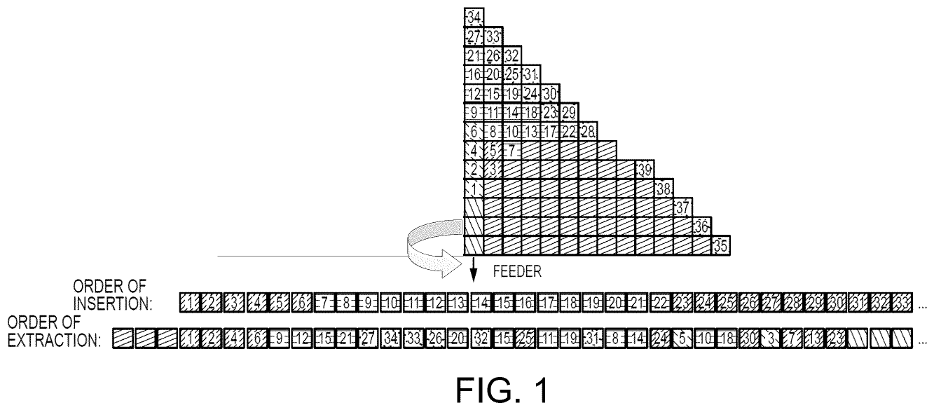

Blocks of material are added to an existing stockpile in sequence (1, then 2, then 3, etc.). However, the order of extraction of the blocks from the feeder at the bottom of the stockpile is often not sequential. In other words, due to subsequent events in the stockpile (or events that may impact the stockpile), the extraction order may not follow the insertion order. Moreover, the order of the extraction of the blocks may be impacted by additional material being added to the stockpile. As the stockpile is increased, reduced or re-arranged (e.g., by dozer), the system may manipulate the blocks by rules and/or physical principles to simulate how the ore may move or blend. For example, to comply with the angle of repose rule, the system may determine that a limited number of blocks may be stacked on top of each other. FIG. 1 shows a model consisting of a (planar) slice of the stockpile from its center on the vertical axis outward to its edge. Each block represents a conceptual doughnut (annulus) created by rotating the block about the center axis for a full 360 degrees. The bottom blocks (without numbers) represent the pre-existing stockpile, then the numbered blocks (having stockpile (e.g., cube) identifiers) are stacked upon the pre-existing stockpile. According to the angle of repose rule, three blocks cannot be stacked on top of each other (without more side support), so block 3 does not stay on top of block 2, but block 3 instead falls down next to block 2. After block 3 provides the side support to block 2, then block 4 is able to stack on top of block 2.

With respect to the cellular automaton, in various embodiments, the system breaks down the process and the IOS into various blocks (e.g., cells), such that the system may move the blocks around according to various rules to create a simulation. The cellular automaton may include a collection of cells arranged in a grid or lattice having a specific shape (e.g., the shape of an IOS). Each cell may change state (e.g., position) as a function of time, based on rules that are driven by the states of neighboring cells. These rules can be iteratively applied for as many time steps as required. In each time unit, the cells represent one of a finite set of states. The cells may evolve in parallel at discrete time steps by considering the states of neighboring cells. The use of cellular automaton is a simpler and more discrete form of discrete particle analysis (or particle simulation). Discrete particle analysis takes a large amount of computing time and is very complex, so discrete particle analysis could not be delivered fast enough for implementing timely adjustments to the system and process. The difference between cellular and discrete may mean that a cell is a higher level representation of a set of discrete particles. In other words, cellular automaton allows the creation of simulations at the molecular level tractable by homogenizing groups of them into cells. However, simulations may no longer be at the molecular level, after looking at macroscopic collections. In various embodiments, the system may include adjustable granularity of simulation (e.g., 1 second time resolution, 1 minute time resolution, 1 hour time resolution, 1 ton mass quanta, 10 ton mass quanta, 100 ton mass quanta, etc.).

In various embodiments, the system may create and/or use a concentrator transit model (e.g., simulation) of the concentrator. The system may use the concentrator transit model to predict when the incoming ore (and the characteristics of the ore) may reach each comminution processing stage. In various embodiments, as part of an initialization process, the system may delay the start of the concentrator transit model and/or delay the recording of the results of the concentrator transit model (as part of a burn-in process). Because this process is a simulation of a physical process, the system may go back to any point in time to start this initialization process. The system may include a variable (or parameter) that may be used to instruct the delayed start of the concentrator transit model to a desired time frame. A convergence period may exist when the concentrator transit model starts. Before the system reaches convergence, the mass in the system may be unreliable. As the mill starts to bring in new mass, the mill may be empty, less than full and/or include mass where the ore composition is not known. In particular, all (or many) of the components and stages (that the concentrator transit model may track) may be empty, less than full and/or include mass where the ore composition is not known. As the mass starts to percolate into the different components of the mill, the components start to fill up and/or the new mass replaces the unknown mass. As such, the concentrator transit model results may initially be unreliable, until the components in the mill have a sufficient amount of new mass for the results to be more reliable. The parameter instructs the system to ignore (or minimize) certain results from the concentrator transit model until the results are more reliable (e.g., the mineralogy in each of the bins is known).

In various embodiments, the system may include adjustable granularity of simulation and run in any increment (e.g., 1 second time resolution, 1 minute time resolution, 1 hour time resolution, 1 ton mass quanta, 10 ton mass quanta, 100 ton mass quanta, etc.). However, because this process is a simulation of a physical process, the system does not need to run in real-time. Rather, the system may backfill and go back to any time frame or period of time to analyze data.

The system knows the ore mineralogy going into the stockpile, simulates the mineralogy exiting the stockpile, exiting the stockpile and through the comminution processing stages. However, the system may not provide the mineralogy of the ore leaving the stockpile at any given time. To help validate the models and simulations, the system may look downstream and use the on-stream analyzers (OSA). Such analyzers, based on X-ray diffraction, for example, may be used to sample (e.g., every 5 minutes) the slurry that is going into floatation and determine the quantities of iron, copper and molybdenum in the ore. While the OSA may need further calibration and may include noise at times, the OSA may still provide effective feedback. The system may compare the determined quantities of, for example, iron, copper and molybdenum for the ore going into floatation against what the concentrator transit model determines are the simulated amounts for the ore going into floatation. Based on the comparison, the system may determine if the model estimates are accurate. The estimates may be real-time estimates or point-in-time estimates for any point in time. If the model estimates are more accurate, then the system may have higher confidence in the results. With higher confidence, the system may determine if it is appropriate to take action based on the estimates. The system may use the feedback to re-train and/or adjust the concentrator transit model's parameters based on any differences in the comparisons.

In various embodiments, the system may (e.g., in real-time) adjust the simulation based on equipment status (e.g., crushers or lines being down). In various embodiments, the system may trigger the simulation based on an event (e.g., when MMT records arrive). The system may include a configuration file that contains the equipment (or component) parameters. The system may track each stockpile cube identifier through each of the processing stages and through each of the components. The cube may no longer exist after the cube goes through comminution, because the system may be tracking mass. The system may obtain data from sensors in various components of the concentrator. As explained in more detail below, the data may be from sensors on the belts, scales and/or bins. The data may include bin levels, speed of conveyors, length of conveyors and the like. The same types of sensors may be associated with similar components on different production lines, so the data from each sensor may be associated with an identifier of the particular component that includes the particular sensor (e.g., sensor data from conveyor 23).

The concentrator transit model is a physical simulation of the processing steps of the comminution process using a concentrator. In various embodiments, the system provides a real-time simulation, predicting and/or tracking based on, for example, sensor input, feeder speed, bin levels, motor speed limits, conveyor characteristics and the like. The predicting and/or concentrator transit model may account for, for example, in-circuit blending, process survival and transit times. The process survival may include the amount of time for the critical mass of a block to leave a process area (inclusive of mass recirculation through the process multiple times). The transit time may include the amount of time for a block to enter a process until the block first begins to exit the process. The concentrator transit model may track the material characteristics through the concentrator. As such, the system connects the MMT data to the concentrator performance. In various embodiments, the system may use pointers and/or master data views to track the material characteristics. The pointers may include, for example, universally unique identifiers (UUID) to MMT records. In other words, the simulation may not need to track the material characteristics; rather, the system may use a pointer to track the material characteristics.

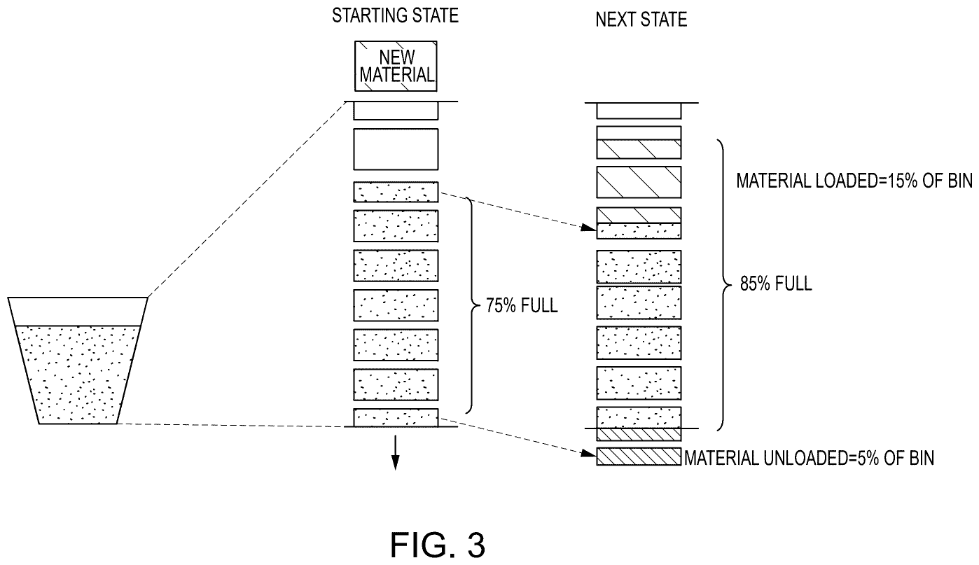

With respect to FIG. 3, the concentrator may include, for example, secondary screen bins that are fed by the IOS feeders. The secondary screen bins may provide material to secondary screen feeders that feed the secondary screen. Depending on the size and type of the material from the secondary screen at that point, the material may be fed to the secondary crusher bins. The secondary crusher bins may provide material to secondary crusher feeders that feed the secondary crusher. Depending on the size and type of the material, the secondary crusher may send the material back through the secondary screening process. Depending on the size and type of the material from the secondary screen at that point, the secondary screen may send the material to tertiary (wet) screen bins. The tertiary screen bins may provide material to tertiary screen feeders that feed the tertiary screen. Depending on the size and type of the material at that point, the tertiary screen may send the material to the tertiary crusher bins. The tertiary crusher bins may provide material to tertiary crusher feeders that feed the tertiary crusher. Depending on the size and type of the material at that point, the tertiary crusher may send the material to the tertiary screen bins. The tertiary screen bins may send the material to the mill feed bins (BX), pump and cyclone devices (e.g., cyclone feed sump, cyclone feed sump pump, and/or hydrocyclone). A cyclone may be a type of size classification device using centrifugal force to separate out smaller and larger particles before the ore moves to the mill or solvent extraction (SX) plant for metal extraction. Depending on the size and type of the material at that point, the cyclone may send the material to the roughers (flotation cells that remove gangue (worthless material) from the ore) and/or to the ball mill (cylindrical grinder and mixer that may use a grinding medium). The ball mill may send the material back through the BX, pump and cyclone devices.

The sensors in the concentrator may include, for example, the belt scale used to measure the tonnage on a conveyor, the bin level used to measure the quantity of material in the secondary screen bin, bin level used to measure the quantity of material in the secondary crusher bin, bin level used to measure the quantity of material in the tertiary crusher bin, bin level used to measure the quantity of material in the tertiary screen bin, belt scale used to understand the tonnage on conveyor connected to mill, and mill level used to measure the quantity of material in the mill. The stockpile model may receive data from sensors such as, for example, mill crush run status, total stockpile tonnage, stockpile tonnage from mill crush, stockpile input from belt scale, stockpile input in a tons per minute (TPM) derived from MMT haul truck tonnage at primary crusher, belt run status, stockpile output from belt scale (e.g., stockpile reclaim belt), TPM derived from belt scale (e.g., stockpile reclaim belt), Kalman-corrected stockpile total mass, uncorrected stockpile total mass, Boolean indication of stockpile mass correction by survey, percent change during survey correction event, percent change to original mass field after a survey correction, new total stockpile mass following correction, ratio of outgoing TPM from belt scale to the Kalman filter estimate, and Kalman filter parameters and covariance. The conveyors may include sensors that determine the tonnage (e.g., tons per hour across the conveyor) on a particular conveyor at any particular timeframe. The tonnage may be used in the concentrator transit model.

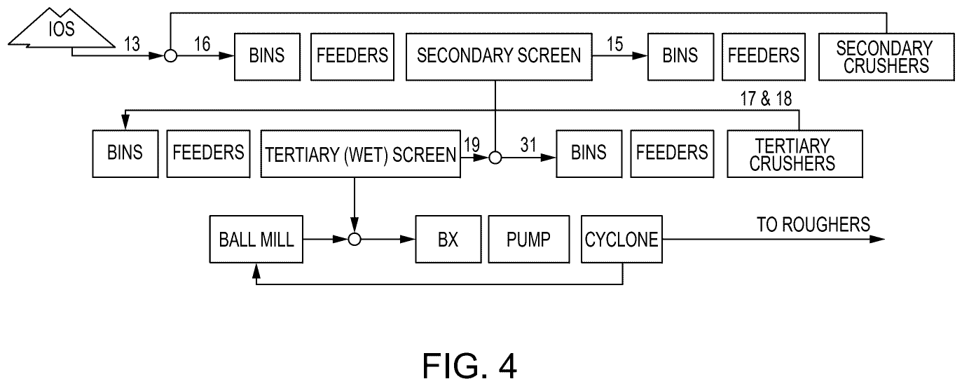

After the block leaves the stockpile, the system records the mineralogy of the block and associates the date and/or time with the block cube identifier (ID). The block enters a screen, so that any material that is over-sized is sent to secondary crushing and any material that is under-sized is sent to tertiary crushing. The system obtains data from the various sensors from the different components in the comminution system. The sensors provide information about the amount of the block that is in a bin, the amount of the block that is in a feeder, the amount of the block that is in secondary crushing and the amount of the block that is in tertiary crushing. Therefore, the system is able to track the portions of the block that are distributed to different components of the comminution system, including data about the mineralogy at each component. In various embodiments, the determination of the material at different components may be in real-time such that the material may be tracked by any timeframe (e.g., by the minute). For example, the system may provide the data every minute. The system may be configured to run approximately every 15 minutes in production. This determination of when to run the system may be dynamic. The system may be implemented with streaming data or event driven execution. To help more evenly distribute the material over a component (and minimize overflow), the conveyor dumps the material into a bin, before entering a crusher or ball mill. With respect to FIG. 4, the system considers the movement of the material in the bins under the principle of first in and first out. As such, the material may not be overly blended while in the bins. However, the blending of the material in the bin may occur when new material is loaded and unloaded. The determination of the material characteristics in the bin helps to determine the material characteristics that are being sent to different components (e.g., secondary crushing, tertiary crushing, wet screens and the like). The bins may be modeled similar to the conveyors, as discussed below. In particular, the bins may include discrete segments with equal mass capacity. The new material is distributed to the available segments at the top of the bin. The material is unloaded from the bin to align the bin level. In various embodiments, the system may determine the material characteristics in bins based on the characteristics of the bins (e.g., capacity of the bins) and various sensors that monitor the bins. The sensors may monitor the material entering the bin and material leaving the bin. Additional sensors may monitor the conveyors over and/or under the bin, so that the system can determine how much material entered and/or left the bin. For example, as set forth in FIG. 4, a sensor may determine that a bin is 75% full in an initial state. In a subsequent state, 5% of the existing material is unloaded from the bin and 15% of the new material is loaded into the bin, so the system determines that the bin is now 85% full.

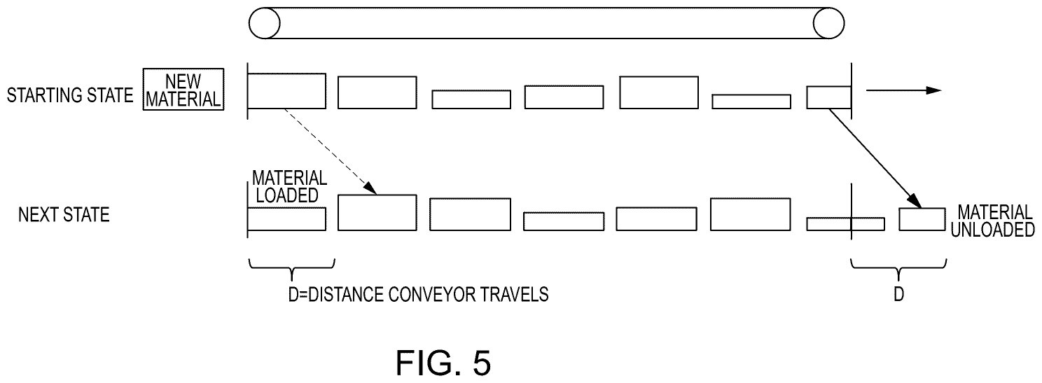

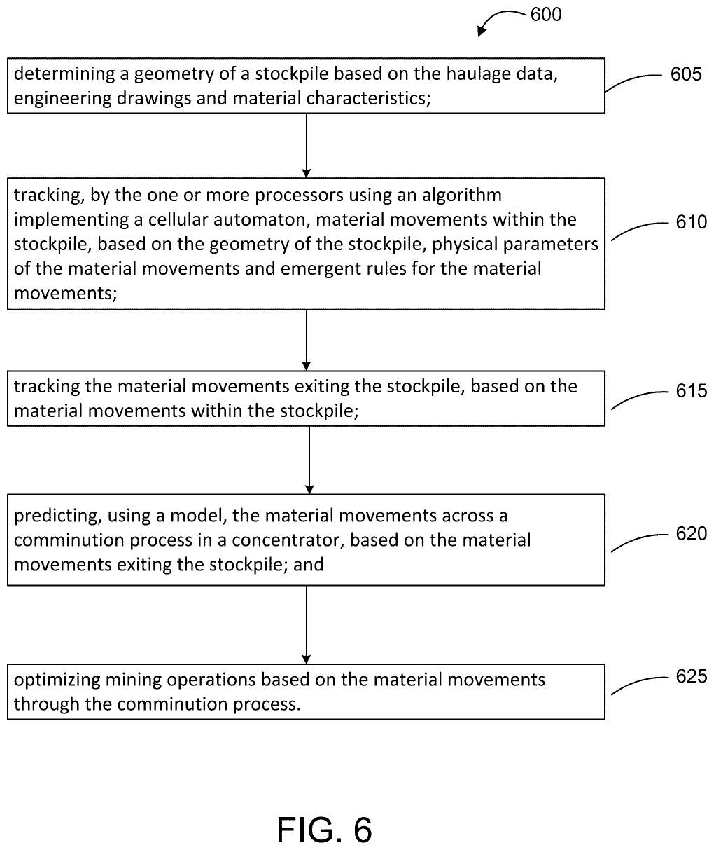

With respect to the models of the conveyor, in various embodiments, the system may simulate the conveyor by segmenting the conveyor into discrete sections. With respect to FIG. 5, each of the conveyor discrete sections may include material having different characteristics. The material characteristics in each of the conveyor sections may include, for example, assay characteristics, quantity (mass) of the material, where the material was extracted from in the mine and the like. The system may determine the material characteristics in a section of the conveyor, the material characteristics that entered the conveyor and the material characteristics that left the conveyor. This determination of the amount of mass in a section may depend on throughput, conveyor speed and the like. The system simulates the actual blending that occurs when the material is loaded onto the conveyor and unloaded from the conveyor. The one or more concentrator transit models may be developed based on the physical layout of the plant. Each process area may be represented in a graph format. Each node may represent a piece of equipment (e.g., bin, crusher, mill, etc.). The system may be validated by analyzing in-plant measurements at each node to ensure that the mass balance (mass in vs mass out) of the system is reflected in the mass movement of the system. The system may include or use discrete trackers injected into the comminution process (e.g., RFIDs) to validate the simulation. Some mass will flow downstream, while some mass will be recirculated upstream (e.g., recirculating load or recirculation). The graphs (and other dashboard readouts) may shift and/or change in real-time based on different pieces of equipment being on and running. The execution of the model accounts for these changes and represents these changes in near real-time.

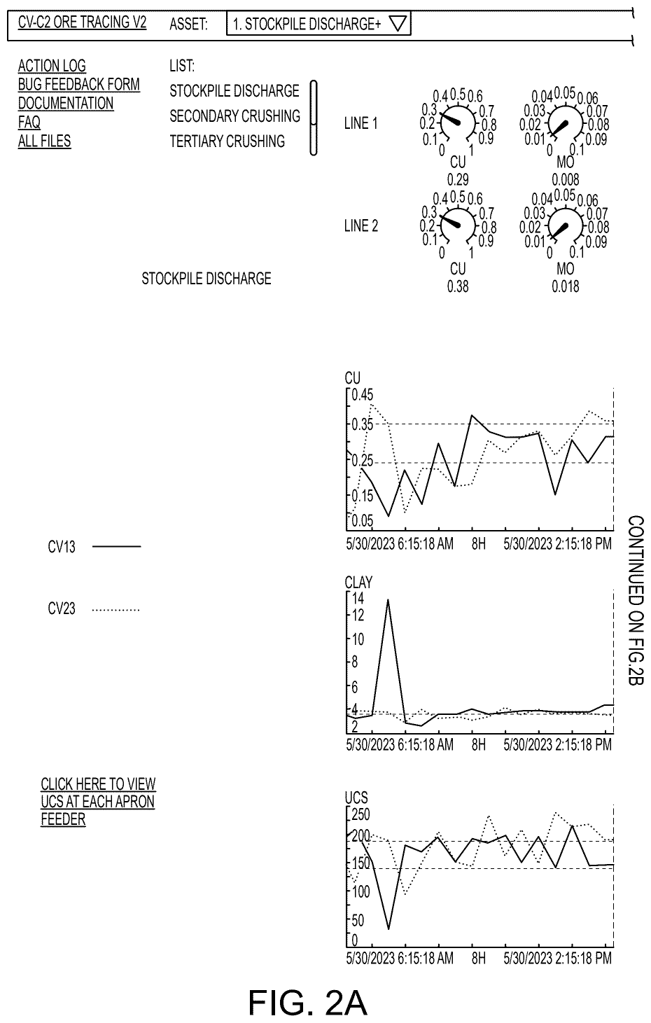

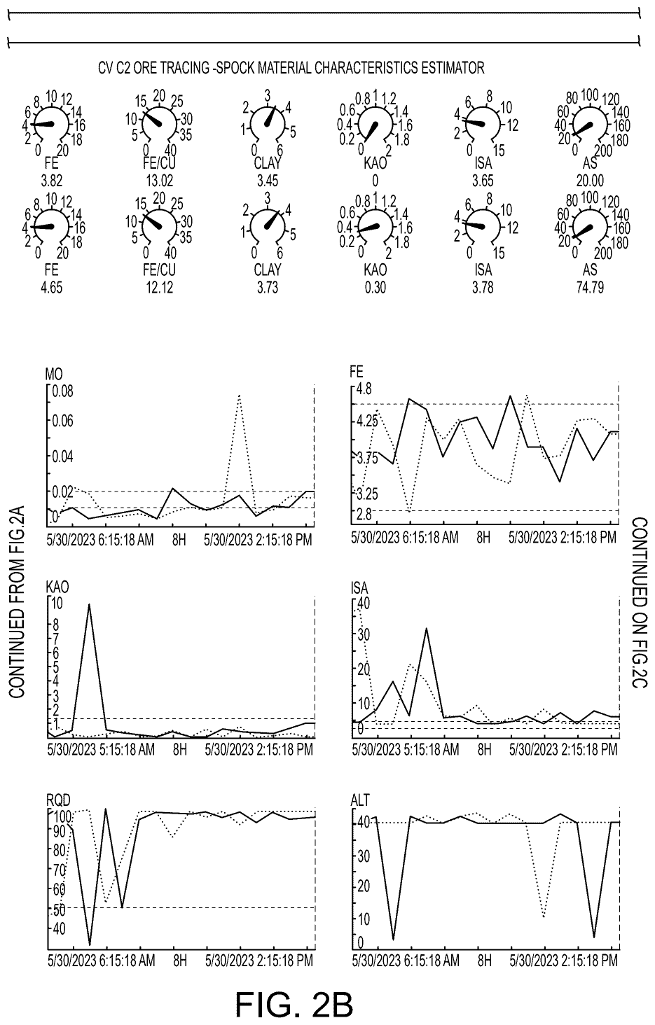

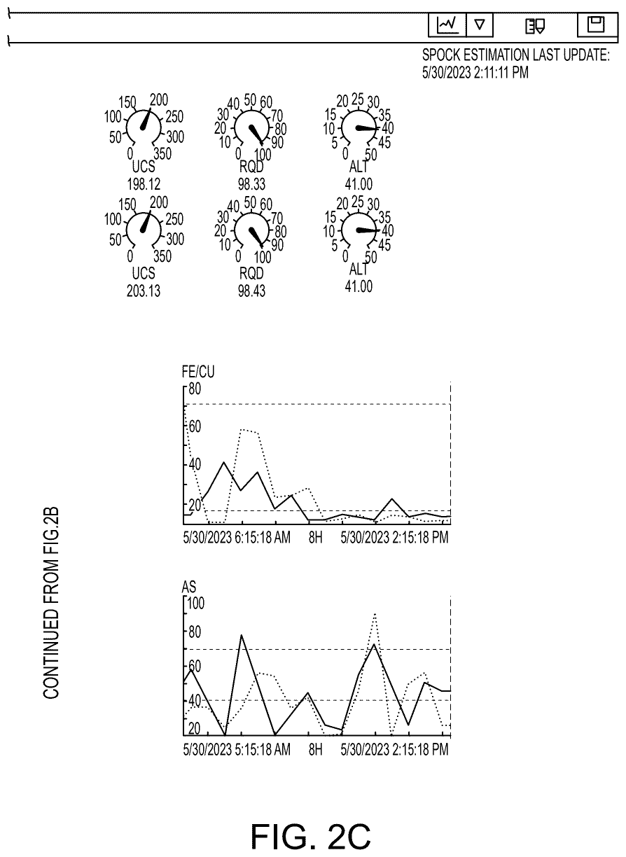

As set forth in FIGS. 2A-2C, in various embodiments, the system may provide a dashboard of the material in the IOS and/or in the concentrator. The dashboard may provide current data and historical data. The system may show the stockpile discharge over time. The system may provide the material characteristics (e.g., mineralogy) over time as the material travels through the stockpile and/or through each of the different components of the concentrator. The short-term view may show the material characteristics that are currently exiting the IOS and the material characteristics that are currently going through the concentrator.

The system may determine ways to optimize current production by considering high ISA (lime strategy), feeder speed (e.g., uniaxial compressive strength (UCS), clay, fines), adding Kaolinite, reagent dosing (chemical conditioning by agglomerating smaller sludge particles), high pressure grinding roles (PGR) (e.g., maximize throughput), add alteration, adding Fe, adding Cu and the like. With respect to acid solubility index (ISA), a high ISA indicates the ore is, for example with respect to copper, more oxide than sulfide copper. The concentrating process typically does not work as well on oxides as the concentrating process works on sulfides. Some minerals may interact with acid and cause the leaching solution to become more acidic, which results in lowering pH outside of desired ranges and requiring the addition of lime to increase pH back up to operating levels. As such, the ISA may represent the percentage of minerals that is likely to cause the pH to be more acidic. With respect to geological alteration, which is the process in which various chemical and physical processes alter a mineral's composition or structure (forming different byproducts and requiring various types of treatment to address), by using information about the type and extent of alteration in an ore body, production can be optimized to treat the altered zones accordingly.

The system may determine ways to optimize current production based on historical production. The system may periodically save all of the data (e.g., every 15 minutes), so the system is able to provide data during any timeframe. For example, if the mining operations find a certain type of material, the system can use the historical database to obtain data from a time frame (e.g., 3-4 years ago) when a similar type of material was previously found and processed. The system may obtain the settings, production environment and mitigation strategies that were used in the past to handle the processing of the similar type of material. The system may also access the historical data to obtain data about the efficacy of a particular reagent that was used in the past to determine if a similar reagent may be helpful in a current scenario. The historical updates may be associated with deploying the historical data to the production environment in which the system operates (PROD), high ISA historical data analysis, molybdenum processing plant, Throughput, Recovery, Optimization and Intelligence (TROI) re-train (e.g., an automated optimization engine that periodically optimizes set points and/or parameters for the mill), merging value chain historical data with a view of incoming ore characteristics and/or the like. With respect to the molybdenum processing plant, moly is often associated with copper, so many operations extract both copper and molybdenum in different steps. However, not every copper extraction correlates to a moly extraction. The historical data is the amount sent to the moly plant for processing. For example, the moly plant may be used for arsenic and talc. The system may identify high ISA conditions and reverse declining trends in rougher recovery. Rougher devices may include the flotation tanks to remove gangue. Rougher recovery is amount of metal extracted from the tanks relative to amount of gangue removed. For example, ore with about 90% gangue material may have a recovery of about 10%. In response to ore with high ISA on the stockpile, the system may increase lime consumption. In response to ore with high clay on the stockpile, the system may change the feed ratio (coarse-fine) on the feeders to avoid plugging the chute for the crushing process.

The proactive management helps to minimize potentially disruptive conditions and avoid bottlenecks in the flow of the material. The proactive management also helps to optimize the mine to mill interface holistically. In various embodiments, the system may adjust plant operations and/or proactively manage multiple processes, based on being able to view the ore characteristics of the ore that exists in the stockpile, exiting the stockpile, entering the concentrator and/or moving through the comminution process. The system may also help to optimize consumables in the processing facility (e.g., water, reagent, CaO, power, etc.). For example, by determining the ore characteristics at different phases in the comminution process, the system may determine the optimum amount of the consumables to use on the ore at different at different phases in the comminution process. As such, the system may avoid using too much or too little consumables during different phases of the comminution process.

The system may provide information about the material hardness, the off-stream mineralogy, high clays, impurities that disrupt reagent dosing, material composition, when the material at the top of the stockpile may enter different components of the concentrator (or phases of the comminution process) and/or the like. With respect to hardness issues, the system may increase draw velocity from center feeders to increase fines. The system may adjust the ball charge (the charge volume of a ball mill or rod mill is the total volume inside the mill where grinding media is added for comminution of ore particles) and power strategy in the mills. With respect to clay issues, the system may reduce fines or ball charge, in anticipation of high clay periods. The system may also reduce water on the belt to compensate for clay issues. With respect to insolubility issues, the system may increase the water with thickeners, in response to a high solubility percentage. This would be a rougher grade strategy. With respect to a moly plant, the system may increase the rougher grade and/or decrease mass pull during periods of high Arsenic deliveries.

In various embodiments, the system may include a value chain historical data that enhances the ability to make data driven decisions and helps to validate and identify strategic opportunities. The value chain historical data may include a data set (e.g., end-to-end data set) that includes all model items, fleet management system (FMS) data and discrete mill performance for analyzing cause and effect. With respect to blend ratios, the system may include a data driven approach to investigate strategies that may be significantly straining the mine. With respect to recovery, the system may include an historical dataset with mineralogy data and geology data. This data may be used to contrast recovery assumptions against actuals. For example, the system may determine if critical items are missing in the assay and targeting coverage. With respect to cost and reliability, the system may enable various analyses. For example, the system may help to analyze liner health impacts by rock type and alteration. Such an analysis may improve cost allocation in the life of mine (LOM) process (which may include improving the mining process), amount of reserves and/or production potential.

The system may improve Throughput, Recovery, Optimization and Intelligence (TROI) by integrating the TROI with the data about the incoming ore characteristics and the data from the value chain historical data. For example, the system may provide TROI with additional information about the material characteristics, changes in the material characteristics and the timing of the material through the processing. As such, the system may significantly improve TROI by making TROI more ore aware and time aware. For example, based on input from the system, the system may integrate a fixed one hour lag feature for UCS, clays, percent insoluble and CuOx from the MMT data. This resulted in reducing model MAPE (mean absolute percentage error) concentrators by about 1 percentage point (p. p.). The system may also provide improved performance in first principal relationships. For example, P80 and hardness, or P80 and clays. The system may re-train one or more section models which may fundamentally change the TROI material characteristic assumptions by utilizing best live estimates of incoming ore composition.

The TROI recommendations may be based on sensor data in the proceeding time frame (e.g., 3 hours). Prior systems may lack the ability to consider what is currently entering the concentrator. Prior systems may not have the ability to detect off stream data (e.g., alteration, UCS). However, the models of the system allow TROI to understand what is entering the concentrator. The concentrator transit model may also tailor recommendations to better reflect the current state of the concentrator. The system may use the historical data to more accurately incorporate model data (which was previously unavailable) into TROI. Before using the system, the achieved MAPE was a higher percentage, but after using the system, the achieved MAPE is a lowered percentage. The system may use the optimum models for P80, Cu and/or Mo recovery.

The system may include quantitative evaluation of minerals (QEMScan) by scanning electron microscopy to implement highly targeted and accurate measurements of ore characteristics in an on-site laboratory. The system may also include an RFID test to help validate the simulation. The system may include or use discrete trackers injected into the comminution process (e.g., RFIDs) to validate the simulation. An RFID test may include putting RFID tags on “shot muck” (e.g., ore ready to be mined post fragmentation in the mine). A sensor may read these RFID tags as the tags exit the primary crushing circuit and enter the stockpile. The RFID tags may then be read again on the belts entering the concentrator. The reading of these RFID tags during different phases may allow the system to measure the amount of time that the ore spent in the stockpile before entering the mill. The system may have data about the truck loads associated with each of these RFID tags, so the system may compare the real-world statistics with the simulation provided by this system. This may allow the simulation parameter to be tuned to optimize performance. In various embodiments, the system may include adjustable granularity of simulation (e.g., 1 second, 1 minute, 1 hour, etc.).

A few use cases may highlight some of the benefits of the system. For example, a mine may have six shovels in a pushback first section of the mine. The pushback section of the mine may include the portion of the open pit currently being actively mined. A mine plan may have a series of pushbacks, each correlating to a different phase of mining to fully extract the ore body. A second section may be mined out, so an additional shovel may be relocated to the first section. As such, the first section may be a significant source of mill ore for the next 12-14 months. However, this first section may be high in Kaolinite, which is a layered silicate clay mineral that has a significant negative impact on recovery. For example, 3 p.p. reduction in recovery may be experienced, for each 1 p.p. increase in Kaolinite. The high Kaolinite may also have a significant negative impact on milling, floatation, thickener, performance and tailing settling. Tailings may be the extraction process waste, along with the waste/gangue from the SX plant, mill, leach heaps, etc. As waste (e.g., tailings) is sent to a tailings impoundment, the water contained in the tailings begins to settle out on top and the waste settles to the bottom, such that the water may be siphoned off the top of the impoundment and reused (recycled) in the processes. In multiple instances, certain concentrators have run at half capacity due to Kaolinite disruptions in water quality due to the tailings. Due to these problems, certain concentrators may be forced to limit deliveries to a lower percentage of the deliveries per hour. Deliveries in excess of this amount may be dumped for re-handling later. After implementing the system for six weeks, a comprehensive processing plan was developed that resulted in large increases in recovery opportunity (e.g., large dollar savings per day) and large increases in throughput opportunity (e.g., a large dollar amount per day). Such throughput opportunity data may be based on a percentage of mill throughput restrictions, along with ad hoc events that may not be continually occurring.

In another scenario, mine deliveries from a certain section of a mine may be significantly higher in Kaolinite and other clays. The higher clays may be common in copper bearing ores, so the clays have been processed in varying quantities in the past. The system found that the high Kaolinite did not always impact recovery negatively. The system found that the various grade items (e.g., quartz, clays, pyrite) may decrease recovery, but increased grind size P80 may increase throughput and pounds produced. The system also found that, when Kaolinite impacted recovery, Kaolinite existed in a greater percentage. The system proved very valuable by providing a data driven Kaolinite limit for all mill deliveries. The system used historical profiles for certain concentrators with numerous mine parameters and mill parameters.

In a further scenario, various ore blends may have different expected performance in the concentrating process. The system used a non-linear clustering method (TSNE) to identify a high quartz content cluster that included a percentage of lower recovery when quartz was greater than a certain percentage. The self-organizing map (SOM) defined ten unique clusters that were not related to the Kaolinite grade. The highest recoveries for the SOM clusters often had unique concentrating parameters. The system proved very valuable by using the expected ore cluster for a given mine to allow the plant to utilize the historical data to adjust mill parameters that have yielded the highest recoveries. The system also enabled ore blends to be adjusted from available mine inventory to target a cluster to help improve mill performance.

In yet another scenario, the mine deliveries may be significantly higher in clays in a certain area of the mine. The water is a primary constraint in the concentrating process, so a concentrator may target at least 25 k m³/hour in water delivery from the tailings process. For a particular concentrator, the system may predict a thickener water recovery leveraging an OLS model with an R² of a certain percentage. R² is a statistical term that may include the statistical accuracy of the data. The important features may include, for example, cyclone overflow P80, flocculant dosage (the chemical or substance added to a suspension to accelerate the rate of flocculation or to strengthen the flocs formed during flocculation), mill throughput, pH in the cyclone overflow and ore type. The system may dynamically adjust how the mill operates for this particular concentrator, based on expected water recovery in the thickener circuit limiting the need to dramatically and suddenly reduce throughput or pull fresh water into the circuit.

In another scenario, material with high clay, such as Muscovite, Kaolinite, Swelling Clay (MKS), is sticky and can result in plugging in the discharge chutes. If ore with high concentrations of clay material exits the stockpile, the unplugging of the discharge chutes may take 20-30 minutes. Fixing the components over time may result in an average of many hours for each shift in downtime. The system shows incoming material characteristics in near real-time, so the system may provide advance notifications of concerns. For example, the system may update approximately every 15 minutes, and may provide minute level granularity for all data points. Based on the notifications, the system may modify the feeder speeds to increase the ratio of coarse material. The increase of coarse material may decrease the impact of high clays exiting the stockpile and entering the concentrator. This modification may reduce the number of bin shutdowns and reduce the total amount of time for the shutdowns. These reductions may result in increased safety and a large savings of tonnage (based on a large amount of tons per operating hour (TPOH) and a large percent reduction in downtime attributable to adjusting the feeder speeds).

The system may also mitigate ISA percentage recovery impacts. Material with high acid solubility percentage (ISA greater than 8%) typically requires increased lime reagent to maintain the copper recovery. In the past, operators could not proactively detect incoming ISA resulting in decreased recovery and lost copper pounds. For example, a previous excursion demonstrated a percent of the recovery dropping, in response to lime being not added. Because the system determines incoming material characteristics in near real-time, the system may determine that high ISA material entered the concentrator on a particular date. The system may identify a process excursion as a trend and increase lime consumption. A process excursion includes deviations from normal operations (inclusive of physical equipment use and normal ore characteristics). Process excursions can be both positive or negative (e.g., high cu grade is positive, while high ISA or MKS is negative). In this example, ISA greater than 8% in the ore blend is a negative process excursion, so the system may take immediate action to adjust lime dosage. The system may continue to provide an ISA prediction to help guide the addition of lime, wherein the system maintains the lime consumption at a high rate to minimize recovery impact. The system may plot (on a graph over time) the ISA percentage and the plant recover percentage. The system may save a large percentage of recovery, including a large amount of money per year based on the number of pounds of copper saved. The savings may also include a large amount of pounds of copper, and a large amount of pounds of copper per year which equates to a large dollar amount per year. These results assume alkalinity is reviewed every 4 hours and changes are implemented based on lagging indicators taken every 2.5 hours. The pounds assume a number of TPH (total petroleum hydrocarbons), a percentage recovery change, a percentage of TCu, 3 high ISA events per month and a certain amount per pound of copper.

The system may periodically determine and report the ore composition in each stage of the comminution process (e.g., secondary crushing, tertiary crushing, grinding, milling, floatation, etc.) to provide a dynamic view of the ore being processed throughout the comminution process. The system may provide material characteristics of the ore to help determine how to adjust (or to send a signal to adjust) different phases, components or actions of the concentrator, mining equipment or mining operations. The system may provide material characteristics during the stockpile phase, the comminution phase and/or the floatation phase. The stockpile phase may include, for example, stockpile changes and residence time. The system may optimize rehandle and blending decisions in the stockpile phase. The comminution phase may include, for example, grinding residence time, mill charging, liner life cycles, cyclone performance and grind size. The system may optimize energy, consumables and costs, while increasing throughput, in the comminution phase. For example, the material characteristics may help determine when to charge the mills. The material characteristics may help determine when to replace the liner (or adjust the amount of time between liner replacements). In particular, if the system determines that an excess of hard, course materials are being processed on the liner, then the liner may not last as long and may need to be replaced earlier (which includes the costly step of taking down the grinding line for a number of hours to complete the replacement). Conversely, if the system determines that softer materials are being processed on the liner, then the liner may last much longer than expected and the replacement may be delayed. The floatation phase may include, for example, flotation residence time, reagent dosage, bubble size, mass pull and density. Based on the material characteristics, during the floatation phase, the system may adjust flotation residence time, reagent dosage, bubble size, mass pull and/or density. The system may optimize metal recovery, product grade, impurity levels, reagent consumption and the like during the flotation phase.

In various embodiments, the system may use the material characteristics, physical modeling and machine learning to perform a dynamic mass balance (DMB) to conduct a reconciliation of material in and material out. The system may use the material characteristics, physical modeling and machine learning as part of a TROI model to predict how the processing plant may behave and how much metal could be recovered under any set of conditions. TROI may be a predictive digital twin model that may use the MMT tool to give real time information about what is going into the crushers and may use the MMT tool to reconcile the geology. The system may use actual results of material in and material out to reconcile and refine the models to help determine a new long-range plan and/or short-range plan. The system may correlate actual performance in the mills with mineralogy in the stockpile models for planning. The system may then be able to implement better planning or physical adjustments to optimize performance and yield.

The planning may include metal recovery performance by plan block. The planning may involve the use of, for example, spatial blocks, geologic data and the like. The improved planning may allow operations to improve reconciliation accuracy. The physical adjustments may include throughput and metal recovery performance by blast adjustments such as, for example, adjustments to drill patterns, blast design, actual blasts, fragmentation and the like. The improved blasting may allow operations to optimize the fragmentation recipe for improved comminution TPOH. For example, the system may determine that the blast process should include blasting coarser material or finer material, depending on the impact of each type of material in the comminution process. The system may improve the loading process by using spatial blocks and loading data. The system may improve the hauling process by using dump location and dump time. The improved loading and hauling may allow operations to improve compliance with the plan.

The timeframe for updating the reporting may track the timing of the MMT updates such as, for example, every 15 minutes. In various embodiments, the system may automatically implement process changes in the concentrator to improve the output of comminution process, based on the concentrator transit model reporting. The operations team may also implement process changes in the concentrator to improve the output of comminution process, based on the concentrator transit model reporting. Some of the process changes may include, for example, changing feeder speeds, changing acid dosages, adjusting the P80, adjusting the reagent addition, handling re-circulating load and the like. To maximize the metal production, the system may also create (or provide the results to other systems that create) the optimal set points (or adjustments) for various settings and levers for different components of the concentrator, based on concentrator performance, available equipment, mineralogy and the like.

In various embodiments, the system may associate the ore that is mined from a particular location (and sent through the comminution process) with the data and results of the comminution process for that particular ore. The system uses the association to understand how the ore from the particular location was processed. The system may then analyze what was done, what was expected to be done and the reconciliation. The system may use those processing results to improve the mining processes, long-term forecasting, short-term forecasting and/or reconciliation.

In general, the MMT input includes data about where the ore was mined, the characteristics of the ore that was mined and where the ore was dumped. The system may create a stockpile model that uses the MMT input to simulate the mixing and blending of the ore in the IOS. The MMT input may include the systems, methods and functions as set forth in U.S. Pat. No. 11,521,138 issued Dec. 6, 2022 entitled “System And Method For Adjusting Leaching Operations Based On Leach Analytic Data” and U.S. application Ser. No. 18/485,143 filed Oct. 11, 2023 entitled “Chemical Impacts On A Leach Stockpile,” both of which are hereby incorporated by reference in their entirety for all purposes.

Certain inputs to the stockpile models and/or other models may include MMT data from a block model, Pro-Vision and dispatch. MMT tracks the material characteristics from the shovel bench to dump location (e.g., primary crusher). More particularly, assays from drill holes may be fed into a tool for 3D interpolation of assays. The 3D assay may be incorporated into a block model. The block model data, the shovel high precision GPS data and modular dispatch data may be inputs into the MMT tool. The rules-based matching may receive inputs from one or more of the haul truck sensors for loading data, dumping data and/or dispatch data. The data from the MMT tool, the ArcGIS section polygons, elevation data, and the rules-based matching may be inputs into the stockpile and section mapping. The stockpile and section mapping, the irrigation data and the heat soft sensor may be part of the feature engineering tools that are fed into the predictive models. The stockpile and section mapping may be fed into the ore map. The system may receive other inputs from other features or data. A report may provide a summary of what happened at the mine over a certain period of time (e.g., 24 hours, a shift, etc.). The report may include information about ore placement, chemical applications, content information, etc. The system may obtain certain information and data from the report to feed into the models. The report information may be obtained from inputted data, sensors, servers, databases, historical data, dispatch data, other systems, etc. The report information may include information from servers because the different sensors may communicate with servers (e.g., PI servers from OSI) such that the servers store all (or a subset of) the sensor data. The system may support storing data from multiple sites and/or from different time zones in the same tables using time zone aware data structures.

The stockpile model provides an understanding of ore placements into the stockpile. In various embodiments, the stockpile model may use drill hole data to map the location of the ore (e.g., in 3 dimensions), head grade, clays, geologic data and/or mineralogic data. The drill hole data may be used determine blast size, blast pattern and a blast plan. The blast does not excessively disrupt the ore, so the location of certain mineralogic areas is still known (e.g., high grade ore area, low grade ore area, high clay area, etc.). The locations of those mineralogic areas may be associated with different shovel loads, truck loads, etc. For example, the system may have data about a specific truck on a specific day obtaining ore from a particular location, and that ore has certain mineralogic features. Based partly on the haul truck sensors and the dispatch system, the system may have data about where the ore was obtained, where the ore is placed in the stockpile, when the ore was placed on the stockpile, the order that the ore was placed on the stockpile and other data about the ore. As such, system includes a full stockpile model of the final placement tracking system.

The stockpile model may provide coordinates for the ore. The ore may be drilled and blasted, then the system re-maps the ore in the stockpile model based on how the ore may have been moved in the blast. The system may provide the data about the new location of the ore and the contents of the ore to the shovel which will load the ore into large haul trucks for transport to appropriate destinations. The system may also include the capturing of dig coordinates with each scoop of the shovel bucket, so the shovel or system can determine if a certain ore section is in that particular scoop. The system may use CAES (computer aided earthmoving system) products called Terrain or ProVision to obtain the scoop data. The system or shovel may determine where the ore should be placed based on the contents of the ore in the scoop, after the ore is scooped up by the shovel. For example, the system may determine that a first ore scoop with more copper content should be placed in a first truck that is scheduled to go to a particular leach stockpile, while a second ore scoop with less copper should be placed in a second truck that may be scheduled to go to a mill or different area.

The system may also include the ore map data flow. The ore map data flow may include a determination of the total mineralogy per stockpile. The system may obtain information from MMT, section mapping, irrigation and polygons. More specifically, the system may join and aggregate mineralogy details to the section level by combining the MMT truckload data at the dump level, the MMT imputation data at the dump level and the MMT final section mapping data (combination of MMT, haul truck sensor and dispatch) at the dump level or section level. The system may also obtain the maximum DUL (days under leach) for each section at the section level by using the irrigation data (raffinate flow, quantity, time, etc.) over all stockpiles at the section level. The intermediate ore map for a stockpile may combine the section level aggregation of mineralogy details, the section level maximum DUL for each section and the primary new section polygon.

The ore map may also include 4D visualization, including x, y, z and time information. The ore map may provide interactive visualization of all (or any subset of) stockpiles, section mineralogy populated on the map of each stockpile, filtering of sections by lift, stockpile or mineralogy composition and/or displaying aggregated values for selected sections. Ore Map 4D visualization (aka “ore finder”) may include determining x, y, z locations of the remaining copper and time-series layering. The ore map may define stockpile and section boundaries based on polygons recorded in GIS. Dump locations of haul trucks may be mapped into these polygons based on combined signals from MMT location information (which obtains information from a beaconing system), GPS coordinates pulled from sensors and other systems on haul trucks and mapping section identifiers and sub-piles to specific leach stockpiles. After the dump locations of trucks are known, the MMT data (associated with all trucks matched to a given section) are aggregated and averaged to estimate section-level characterizations of mineralogy and P80. Recovery from these sections may be estimated based on the column test model, and the remaining copper may be calculated at the section-level by deducting estimated recovered copper from initial placements. Finally, the system may determine which sections are economically viable for recovery via drip, wobbler or injection irrigation based on a number of contiguous high-remaining sections and the proximity of the high-remaining sections to a top lift.

The servers and components may provide information to an enterprise server or database. The system may include a data engineering (DE) pipeline that ingests the raw data, builds out features, aggregates data, builds the dataset for the one or more of the models, creates output shapes and/or provides output. The DE pipeline may include SQL queries, feature engineering in any suitable code (e.g., Python code), etc. The DE pipeline may generate model input tables for a feature store. The feature store may include a data cloud or warehouse (e.g., Snowflake data cloud) where the data is written out from the DE pipeline or a database (e.g., Cosmos database) that stores different models and results (forecasts, backcasts, etc.). The feature store may provide data for model training, etc. The system may support storing data from multiple sites and/or from different time zones in the same tables using time zone aware data structures.

In various embodiments, the dispatch system may be used for tracking equipment status and/or position. The dispatch data may be used in the MMT and/or the Rules-based Matching. The dispatch system may also include cycle optimization (e.g., routing and scheduling based on mining operations as well as capacities of crusher, etc.), balance idle equipment times, balance queue times, manage fuel, operator's performance, productivity, etc. A typical haulage cycle may include receiving truck loads from the assigned shovel, traveling with a full truckload to an assigned dumping location, arriving at the dump queue, dumping the load, traveling empty back to the assigned shovel, arriving at the shovel queue, spotting, and then the cycle may repeat. The haulage cycle data may include a shovel identifier, a shovel location identifier, a truck identifier, a load time and data and a stockpile identifier. The spotting may be the appropriate locations for the truck to be able to receive the ore from the shovel or the appropriate locations for the truck to be able dump its load in the appropriate section.

Rules-based matching is used to analyze two or more inputs about where a haul truck may have placed a load. A dispatch system (e.g., modular dispatch system) may include a beacon system that may provide data about the time a truck arrived at a certain location and dumped a load. The dispatch system may set a beacon many miles away from the dump location based on how the stockpile or lift may be configured. The truck sensor may provide data about a truck dumping a load at a particular location (e.g., latitude, longitude and elevation) and at a particular time. The truck sensors may include one or more sensors that may be added to trucks by the original equipment manufacturer (OEM), added to the trucks by the OEM based on a customer request and/or added to the trucks by a customer. For example, some trucks may have over 350 different sensors that provide data about different aspects of the truck and its actions. The sensors may include GPS sensors that provide GPS data about the location or movement of the truck, load sensors that may track the weight of the load, dump sensors that may track the bed position, energy sensors that may track the amount of energy (e.g., gas, propane, electric, etc.) stored in the truck or being used by the truck, gear sensor that may monitor that gear placement in the truck, a brake sensor that may monitor when the emergency brake is set, etc. The system may also include soft sensors. A soft sensor (software sensor or virtual sensor) may provide an indirect measurement using a combination of process data (input) and a model that uses the input data to predict a target quantity (output). The input data used for the prediction may be composed of signals from hardware sensors and actuators. The soft sensor may process several measurements together using control theory.

The system may use rules to determine that a dump occurred based on, for example, the truck not moving (or speed below a threshold), the truck gear is in park, the emergency brake being set and the bed position passing a threshold height. The system may presume that the truck sensor data is accurate, unless the system determines (e.g., based on a series of rules) that the sensor is broken, a sensor is not located on the truck and/or the dispatch location should be trusted instead. If the system determines that the sensor data and the dispatch data may not be sufficiently accurate, then the system puts the truck load in a dummy location. The system may use the dummy location to account for the load being dumped, but the system may not know precisely where the load was dumped.

Mine vehicles (e.g., haul trucks) typically include a sensor (e.g., OEM sensor) that provides GPS readings. GPS sensor readings may provide the x, y, and z coordinates of vehicles making dumps to a particular lift on a stockpile. The sensor may be read at a time preceding the dump (e.g., 30 seconds before the dump) because the sensors are more accurate while the truck is moving. In various embodiments, the coordinates may be aggregated and averaged in order to determine the physical location of the vehicle as it approaches and then dumps the ore. The elevation data may be used to determine the elevation of the lift. Deducting the analogous elevation measurement from the prior lift provides a mechanism to calculate stockpile (or top lift) height from sequential measurements of the lift heights in the stockpile. For crush-for-leach stockpiles, the lift height may be set by the conveyor height, wherein the conveyor may have a sensor that provides the conveyor height to the system. The ore map may be used for conveyor stacked stockpiles and may include conveyor location data, belt sampler data, etc.

Because trucks travel across the top of the lift of the stockpile that they are building, the further aggregation of measurements from multiple vehicles serves to estimate the boundary of the stockpile's top lift. For example, the system may determine the paths traversed by each truck and form a boundary around all of the paths, and the truck path boundary may estimate the boundary of the stockpile's top lift. In various embodiments, the system may revise the boundary elevation over time using sensors that measure points on the surface or interior of the stockpile. In various embodiments, the aggregated x, y, z information from the trucks may be compared with defined GIS Polygons and dispatch information to provide more accurate dump location precision. Such a comparison may be helpful to improve the accuracy of the dump location due to potential errors from periodic overlap in polygons, dispatch recording a different beacon dump location, or other manual dump location entry errors. A polygon feature may be a GIS object that stores its geographic representation as one of its properties (or fields) in the row in the database. The geographic representation may include a series of x and y coordinate pairs that enclose an area. A geographic information system (GIS) is a computer-based tool for mapping and analyzing things that exist and events that happen on Earth. GIS technology integrates common database operations such as query and statistical analysis with the unique visualization and geographic analysis benefits offered by maps.

With respect to stockpile and section mapping, in general, the system may receive the dump location information (e.g., from MMT and truck sensors). The system may combine the dump location information with GIS polygons. The GIS polygons include information about the section of the stockpile that the load was dumped, including name, characteristics, physical location in x, y, z space, etc. Thus, the system provides information about where in a stockpile the dumped ore exists (and may exist in perpetuity until re-mined in the future). Based on this information, the system may provide a map of (and target) a specific section in a specific stockpile and at an x, y, z location that a truck dumped ore. The system may build a composite of all of the dumps inside this section of this stockpile.

More specifically, for each stockpile, the system may obtain the MMT section mapping data table by combining or joining the MMT truckload data to get the dump location, the location data to obtain the x, y coordinates for each dump location, the dump data to get the GPS x, y location from dispatch and the section data to get the section polygon. The system may combine the MMT section mapping tables from stockpiles in a mine into a MMT section mapping dispatch data table for the mine. The system may obtain the MMT section mapping haul truck data table by combining or joining the MMT truckload data to get the dump location, the location data, the dump data to get the dump identifier, the section data to get the section polygon, the haul truck idle at dump data to get the dump start and end timing and the sensor fixed interval data to get the haul truck GPS longitude and latitude. The MMT section mapping for a mine may combine the MMT section mapping dispatch data table, the MMT section mapping haul truck data table and the haul truck GPS status (that provides GPS quality). The system may preform a preprocessing step to handle sections with overlap. The system may combine the data into different tables such as, for example, the section polygon table, the dump location lift map (dispatch) and the haul truck dump location based on GPS. The haul truck dump location based on GPS may be sent to a haul truck (sensor) section mapping. The section polygon table and the dump location lift map may be combined into a dispatch section mapping table. The MMT section mapping table may be a combination of the dispatch section mapping table and the haul truck (sensor) section mapping.

The system may also obtain data from various tools. In various embodiments, the Mine Material Tracking (MMT) tool may receive data from HPGPS load points, mine data (e.g., from a MineSight system) and/or dispatch data. The HPGPS load points may include Terrain or Provision, along with the HPGPS Loading System that includes dig points. The mine system (e.g., MineSight) may include mine planning and/or mining operations software that includes stockpile model files. The dispatch data may include data from a Mine Fleet Management System (FMS) that provides haulage cycle data and/or beacon data. In various embodiments, the MMT tool may link the stockpile model (to get material characteristics) to individual truck loads.

The MMT tool may allow ore to be tracked from blast to dump at individual truckload locations. The MMT tool may collect and aggregate ore characteristics information at a truckload-by-truckload level. The tool may allow for downstream processes to leverage the stockpile model geologic information, a highly targeted understanding of ore deliveries and locations, and reconciliation of dispatch information with physical processes. The tool may be used for productivity reporting, recovery modeling and other analyses. The MMT tool may also provide data management and data integration functionality to allow mine engineers to review and control the final data output. The MMT tool may provide the users with a much more granular and useful dataset than what may be possible with using only fleet management system data. The MMT tool may integrate with the stockpile model data to provide real-time tracking (e.g., past 24 hours percent TCu deliveries) and improved process modeling and analysis (e.g., past 24 hours percent TClay deliveries).

In various embodiments, the MMT may include SDR (size distribution reporting) to help in obtaining particle size distribution information (e.g., P80) from capturing images of truck loads. The MMT tool may measure SDR data and the SDR data may serve as a predictive variable that contributes to the estimation of stockpile-level copper production via an observational machine learning model.

As will be appreciated by one of ordinary skill in the art, the system may be embodied as a customization of an existing system, an add-on product, a processing apparatus executing upgraded software, a stand-alone system, a distributed system, a method, a data processing system, a device for data processing, and/or a computer program product. Accordingly, any portion of the system or a module may take the form of a processing apparatus executing code, an internet-based embodiment, an entirely hardware embodiment, or an embodiment combining aspects of the internet, software, and hardware. Furthermore, the system may take the form of a computer program product on a computer-readable storage medium having computer-readable program code means embodied in the storage medium.

The operations may be machine operations or any of the operations may be conducted or enhanced by artificial intelligence (AI) or machine learning. AI may refer generally to the study of agents (e.g., machines, computer-based systems and the like.) that perceive the world around them, form plans, and make decisions to achieve their goals. Foundations of AI include mathematics, logic, philosophy, probability, linguistics, neuroscience, and decision theory. Many fields fall under the umbrella of AI, such as computer vision, robotics, machine learning, and natural language processing. Useful machines for performing the various embodiments include general purpose digital computers or similar devices. The AI or ML may store data in a decision tree in a novel way. The system may train a neural network when using artificial intelligence or machine learning. The system may compute a training object. The system may update the one or more of the models based on a training objective. The system may include an expanded data set of past data to train the neural network. The expanded training set may be developed by applying mathematical algorithms to the acquired set of data. The neural network is then trained with the expanded data set using a machine learning algorithm that uses a mathematical function to adjust certain weighting. The system may also use an iterative training algorithm to re-train with additional data.

The system may include remote access to data, standardizing data and allowing remote users to share information in real time. The system may allow users to access data (e.g., data from purchase orders, etc.), and receive updated data in real time from other users. The system may store the data (e.g., in a non-standardized format) in a plurality of storage devices, provide remote access over a network so that users may update the data that was in a non-standardized format (e.g., dependent on the hardware and software platform used by the user) in real time through a GUI, convert the updated data that was input (e.g., by a user) in a non-standardized form to the standardized format, automatically generate a message (e.g., containing the updated data) whenever the updated data is stored and transmit the message to the users over a computer network in real time, so that the user has immediate access to the up-to-date data. The system may allow remote users to share data in real time in a standardized format, regardless of the format (e.g. non-standardized) that the information was input by the user.

The system may include a filtering tool that is remote from the end user and provides customizable filtering features to each end user. The filtering tool may provide customizable filtering by filtering access to the data. The filtering tool may identify data or accounts that communicate with the server and may associate a request for content with the individual account. The system may include a filter on a local computer and a filter on a server. The filtering tool may identify information or accounts that communicate with the server, and associate a request for content with the individual account. The system may include a filter on a local computer and a filter on a server.

The system may store elements from different host websites in a database, then when a user accesses the database, the system may provide a hybrid webpage that merges content or documents from the different host websites. Upon access, the system may merge the content from the various websites and provide a link to the user to access the merged data in the form of an image-based document.

The system contemplates uses in association with web services, utility computing, pervasive and individualized computing, security and identity solutions, autonomic computing, cloud computing, commodity computing, mobility and wireless solutions, open source, biometrics, grid computing, and/or mesh computing. “Cloud” or “Cloud computing” includes one or more models for enabling convenient, on-demand network access to a shared pool of configurable computing resources (e.g., networks, servers, storage, applications, and services) that can be rapidly provisioned and released with minimal management effort or service provider interaction. Cloud computing may include location-independent computing, whereby shared servers provide resources, software, and data to computers and other devices on demand.

In various embodiments, the system and various components may integrate with one or more smart digital assistant technologies. For example, exemplary smart digital assistant technologies may include the ALEXA® system developed by the AMAZON® company, the GOOGLE HOME® system developed by Alphabet, Inc., the HOMEPOD® system of the APPLE® company, and/or similar digital assistant technologies. The ALEXA® system, GOOGLE HOME® system, and HOMEPOD® system, may each provide cloud-based voice activation services that can assist with tasks, entertainment, general information, and more. All the ALEXA® devices, such as the AMAZON ECHO®, AMAZON ECHO DOT®, AMAZON TAP®, and AMAZON FIRE® TV, have access to the ALEXA® system. The ALEXA® system, GOOGLE HOME® system, and HOMEPOD® system may receive voice commands via its voice activation technology, activate other functions, control smart devices, and/or gather information. For example, the smart digital assistant technologies may be used to interact with music, emails, texts, phone calls, question answering, home improvement information, smart home communication/activation, games, shopping, making to-do lists, setting alarms, streaming podcasts, playing audiobooks, and providing weather, traffic, and other real time information, such as news. The ALEXA®, GOOGLE HOME®, and HOMEPOD® systems may also allow the user to access information about eligible transaction accounts linked to an online account across all digital assistant-enabled devices.

The system contemplates uses in association with web services, utility computing, pervasive and individualized computing, security and identity solutions, autonomic computing, cloud computing, commodity computing, mobility and wireless solutions, open source, biometrics, grid computing, and/or mesh computing.

As used herein, big data may refer to partially or fully structured, semi-structured, or unstructured data sets including millions of rows and hundreds of thousands of columns. Big data sets may be compiled without descriptive metadata such as column types, counts, percentiles, or other interpretive-aid data points. The data may be big data that is processed by a distributed computing cluster. The distributed computing cluster may be, for example, a HADOOP® software cluster configured to process and store big data sets with some of nodes comprising a distributed storage system and some of nodes comprising a distributed processing system. In that regard, distributed computing cluster may be configured to support a HADOOP® software distributed file system (HDFS) as specified by the Apache Software Foundation at www.hadoop.apache.org/docs.

Association of certain data may be accomplished through any desired data association technique such as those known or practiced in the art. For example, the association may be accomplished either manually or automatically. Automatic association techniques may include, for example, a database search, a database merge, GREP, AGREP, SQL, using a key field in the tables to speed searches, sequential searches through all the tables and files, sorting records in the file according to a known order to simplify lookup, and/or the like. The association step may be accomplished by a database merge function, for example, using a “key field” in pre-selected databases or data sectors. Various database tuning steps are contemplated to optimize database performance. For example, frequently used files such as indexes may be placed on separate file systems to reduce In/Out (“I/O”) bottlenecks.

More particularly, a “key field” partitions the database according to the high-level class of objects defined by the key field. For example, certain types of data may be designated as a key field in a plurality of related data tables and the data tables may then be linked on the basis of the type of data in the key field. The data corresponding to the key field in each of the linked data tables is preferably the same or of the same type. However, data tables having similar, though not identical, data in the key fields may also be linked by using AGREP, for example. In accordance with one embodiment, any suitable data storage technique may be utilized to store data without a standard format. Data sets may be stored using any suitable technique, including, for example, storing individual files using an ISO/IEC 7816-4 file structure; implementing a domain whereby a dedicated file is selected that exposes one or more elementary files containing one or more data sets; using data sets stored in individual files using a hierarchical filing system; data sets stored as records in a single file (including compression, SQL accessible, hashed via one or more keys, numeric, alphabetical by first tuple and the like.); data stored as Binary Large Object (BLOB); data stored as ungrouped data elements encoded using ISO/IEC 7816-6 data elements; data stored as ungrouped data elements encoded using ISO/IEC Abstract Syntax Notation (ASN.1) as in ISO/IEC 8824 and 8825; other proprietary techniques that may include fractal compression methods, image compression methods and the like.

In various embodiments, the ability to store a wide variety of information in different formats is facilitated by storing the information as a BLOB. Thus, any binary information can be stored in a storage space associated with a data set. As discussed above, the binary information may be stored in association with the system or external to but affiliated with the system. The BLOB method may store data sets as ungrouped data elements formatted as a block of binary via a fixed memory offset using either fixed storage allocation, circular queue techniques, or best practices with respect to memory management (e.g., paged memory, least recently used and the like.). By using BLOB methods, the ability to store various data sets that have different formats facilitates the storage of data, in the database or associated with the system, by multiple and unrelated owners of the data sets. For example, a first data set which may be stored may be provided by a first party, a second data set which may be stored may be provided by an unrelated second party, and yet a third data set which may be stored may be provided by a third party unrelated to the first and second party. Each of these three exemplary data sets may contain different information that is stored using different data storage formats and/or techniques. Further, each data set may contain subsets of data that also may be distinct from other subsets.

As stated above, in various embodiments, the data can be stored without regard to a common format. However, the data set (e.g., BLOB) may be annotated in a standard manner when provided for manipulating the data in the database or system. The annotation may comprise a short header, trailer, or other appropriate indicator related to each data set that is configured to convey information useful in managing the various data sets. For example, the annotation may be called a “condition header,” “header,” “trailer,” or “status,” herein, and may comprise an indication of the status of the data set or may include an identifier correlated to a specific issuer or owner of the data. In one example, the first three bytes of each data set BLOB may be configured or configurable to indicate the status of that particular data set; e.g., LOADED, INITIALIZED, READY, BLOCKED, REMOVABLE, or DELETED. Subsequent bytes of data may be used to indicate for example, the identity of the issuer, user, transaction/membership account identifier or the like. Each of these condition annotations are further discussed herein.

The data set annotation may also be used for other types of status information as well as various other purposes. For example, the data set annotation may include security information establishing access levels. The access levels may, for example, be configured to permit only certain individuals, levels of employees, companies, or other entities to access data sets, or to permit access to specific data sets based on the transaction, merchant, issuer, user, or the like. Furthermore, the security information may restrict/permit only certain actions, such as accessing, modifying, and/or deleting data sets. In one example, the data set annotation indicates that only the data set owner or the user are permitted to delete a data set, various identified users may be permitted to access the data set for reading, and others are altogether excluded from accessing the data set. However, other access restriction parameters may also be used allowing various entities to access a data set with various permission levels as appropriate.

The data, including the header or trailer, may be received by a standalone interaction device configured to add, delete, modify, or augment the data in accordance with the header or trailer. As such, in one embodiment, the header or trailer is not stored on the transaction device along with the associated issuer-owned data, but instead the appropriate action may be taken by providing to the user, at the standalone device, the appropriate option for the action to be taken. The system may contemplate a data storage arrangement wherein the header or trailer, or header or trailer history, of the data is stored on the system, device or transaction instrument in relation to the appropriate data.

One skilled in the art will also appreciate that, for security reasons, any databases, systems, devices, servers, or other components of the system may consist of any combination thereof at a single location or at multiple locations, wherein each database or system includes any of various suitable security features, such as firewalls, access codes, encryption, decryption, compression, decompression, and/or the like.

Practitioners will also appreciate that there are a number of methods for displaying data within a browser-based document. Data may be represented as standard text or within a fixed list, scrollable list, drop-down list, editable text field, fixed text field, pop-up window, and the like. Likewise, there are a number of methods available for modifying data in a web page such as, for example, free text entry using a keyboard, selection of menu items, check boxes, option boxes, and the like.

Any database discussed herein may comprise a distributed ledger maintained by a plurality of computing devices (e.g., nodes) over a peer-to-peer network. Each computing device maintains a copy and/or partial copy of the distributed ledger and communicates with one or more other computing devices in the network to validate and write data to the distributed ledger. The distributed ledger may use features and functionality of blockchain technology, including, for example, consensus-based validation, immutability, and cryptographically chained blocks of data. The blockchain may comprise a ledger of interconnected blocks containing data. The blockchain may provide enhanced security because each block may hold individual transactions and the results of any blockchain executables. Each block may link to the previous block and may include a timestamp. Blocks may be linked because each block may include the hash of the prior block in the blockchain. The linked blocks form a chain, with only one successor block allowed to link to one other predecessor block for a single chain. Forks may be possible where divergent chains are established from a previously uniform blockchain, though typically only one of the divergent chains will be maintained as the consensus chain. In various embodiments, the blockchain may implement smart contracts that enforce data workflows in a decentralized manner. The system may also include applications deployed on user devices such as, for example, computers, tablets, smartphones, Internet of Things devices (“IoT” devices) and the like. The applications may communicate with the blockchain (e.g., directly or via a blockchain node) to transmit and retrieve data. In various embodiments, a governing organization or consortium may control access to data stored on the blockchain. Registration with the managing organization(s) may enable participation in the blockchain network.

Data transfers performed through the blockchain-based system may propagate to the connected peers within the blockchain network within a duration that may be determined by the block creation time of the specific blockchain technology implemented. For example, on an ETHEREUM®-based network, a new data entry may become available within about 13-20 seconds as of the writing. On a HYPERLEDGER® Fabric 1.0 based platform, the duration is driven by the specific consensus algorithm that is chosen and may be performed within seconds. In that respect, propagation times in the system may be improved compared to existing systems, and implementation costs and time to market may also be drastically reduced. The system also offers increased security at least partially due to the immutable nature of data that is stored in the blockchain, reducing the probability of tampering with various data inputs and outputs. Moreover, the system may also offer increased security of data by performing cryptographic processes on the data prior to storing the data on the blockchain. Therefore, by transmitting, storing, and accessing data using the system described herein, the security of the data is improved, which decreases the risk of the computer or network from being compromised.

In various embodiments, the system may also reduce database synchronization errors by providing a common data structure, thus at least partially improving the integrity of stored data. The system also offers increased reliability and fault tolerance over traditional databases (e.g., relational databases, distributed databases and the like.) as each node operates with a full copy of the stored data, thus at least partially reducing downtime due to localized network outages and hardware failures. The system may also increase the reliability of data transfers in a network environment having reliable and unreliable peers, as each node broadcasts messages to all connected peers, and, as each block comprises a link to a previous block, a node may quickly detect a missing block and propagate a request for the missing block to the other nodes in the blockchain network.

The particular blockchain implementation described herein provides improvements over conventional technology by using a decentralized database and improved processing environments. In particular, the blockchain implementation improves computer performance by, for example, leveraging decentralized resources (e.g., lower latency). The distributed computational resources improves computer performance by, for example, reducing processing times. Furthermore, the distributed computational resources improve computer performance by improving security using, for example, cryptographic protocols.

As used in this document, “each” refers to each member of a set or each member of a subset of a set. Furthermore, any reference to singular includes plural embodiments, and any reference to more than one component may include a singular embodiment. Although specific advantages have been enumerated herein, various embodiments may include some, none, or all of the enumerated advantages.

Systems, methods, and computer program products are provided. In the detailed description herein, references to “various embodiments,” “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

As defined herein, “real-time” can, in some embodiments, be defined with respect to operations carried out as soon as practically possible upon occurrence of a triggering event. A triggering event can include receipt of data necessary to execute a task or to otherwise process information. Because of delays inherent in transmission and/or in computing speeds, the term “real time” encompasses operations that occur in “near” real time or somewhat delayed from a triggering event. In a number of embodiments, “real time” can mean real time less a time delay for processing (e.g., determining) and/or transmitting data. The particular time delay can vary depending on the type and/or amount of the data, the processing speeds of the hardware, the transmission capability of the communication hardware, the transmission distance, etc. However, in many embodiments, the time delay can be less than approximately one second, two seconds, five seconds, or ten seconds.

As defined herein, “approximately” can, in some embodiments, mean within plus or minus ten percent of the stated value. In other embodiments, “approximately” can mean within plus or minus five percent of the stated value. In further embodiments, “approximately” can mean within plus or minus three percent of the stated value. In yet other embodiments, “approximately” can mean within plus or minus one percent of the stated value.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure. The scope of the disclosure is accordingly limited by nothing other than the appended claims, in which reference to an element in the singular is not intended to mean “one and only one” unless explicitly so stated, but rather “one or more.” Moreover, where a phrase similar to ‘at least one of A, B, and C’ or ‘at least one of A, B, or C’ is used in the claims or specification, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C. Although the disclosure includes a method, it is contemplated that it may be embodied as computer program instructions on a tangible computer-readable carrier, such as a magnetic or optical memory or a magnetic or optical disk. All structural, chemical, and functional equivalents to the elements of the above-described various embodiments that are known to those of ordinary skill in the art are expressly incorporated herein by reference and are intended to be encompassed by the present claims. Moreover, it is not necessary for a device or method to address each and every problem sought to be solved by the present disclosure for it to be encompassed by the present claims. Furthermore, no element, component, or method step in the present disclosure is intended to be dedicated to the public regardless of whether the element, component, or method step is explicitly recited in the claims. No claim element is intended to invoke 35 U.S.C. § 112(f) unless the element is expressly recited using the phrase “means for” or “step for”. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A method comprising:
determining a geometry of a stockpile based on the haulage data, engineering drawings and material characteristics;
predicting, by the one or more processors using an algorithm implementing a cellular automaton, material movements within the stockpile, based on the geometry of the stockpile, physical parameters of the material movements and emergent rules for the material movements;
predicting the material movements exiting the stockpile, based on the material movements within the stockpile;
predicting, using a concentrator transit model, the material movements across a comminution process in a concentrator, based on the material movements exiting the stockpile; and
optimizing mining operations based on the material movements through the comminution process.

2. The method of claim 1, wherein the material movements include the material characteristics.

3. The method of claim 1, wherein the predicting the material movements across the comminution process further comprises modeling bins using the concentrator transit model.

4. The method of claim 1, wherein the material movements exiting the stockpile include timing of the material exiting the stockpile and material composition exiting the stockpile.

5. The method of claim 1, further comprising optimizing fragmentation during the blast to improve the comminution process.

6. The method of claim 1, further comprising determining throughput by the blast.

7. The method of claim 1, further comprising adjusting the comminution process, based on the mineralogy entering the concentrator.

8. The method of claim 1, further comprising predicting material movements through the comminution process in the concentrator.

9. The method of claim 1, wherein the predicting the material movements across a comminution process includes at least one of incorporating a configuration file of component parameters into the concentrator transit model or providing a real-time simulation of the material movements.

10. The method of claim 1, further comprising tracking an identifier of a unit of mass through the comminution process.

11. The method of claim 1, wherein the concentrator transit model accounts for at least one of in-circuit blending, process survival or transit times.

12. The method of claim 1, wherein the predicting the material movements across the comminution process is based on at least one of sensor input, feeder speed, bin levels, motor speed limits, or conveyor characteristics.

13. The method of claim 1, wherein the predicting the material movements is in real-time.

14. The method of claim 1, wherein the predicting the material movements across the comminution process includes at least one of:
monitoring the material entering a bin and monitoring the material leaving the bin, based on segments of the bin, conveyors feeding the bin and conveyors under the bin; or
monitoring the material entering a conveyor and monitoring the material leaving the conveyor, based on segments of the conveyor, throughput of the conveyor, length of the conveyor and speed of the conveyor.

15. The method of claim 1, further comprising optimizing the comminution process based on the material movements through the comminution process.

16. The method of claim 1, wherein the haulage data is based on dump location data and dump time.

17. The method of claim 1, further comprising:
determining metal recovery performance for a plan block;
determining additional of the metal recovery performance by blast;
determining loading data by spatial block; and
predicting material characteristics based on the metal recovery performance, the loading data and the haulage data.

18. The method of claim 1, further comprising displaying material characteristics of the material movement over time.

19. An article of manufacture including one or more non-transitory, tangible computer readable storage mediums having instructions stored thereon that, in response to execution by one or more processors, cause the one or more processors to perform operations comprising:
determining, by the one or more processors, a geometry of a stockpile based on the haulage data, engineering drawings and material characteristics;
predicting, by the one or more processors using an algorithm implementing a cellular automaton, material movements within the stockpile, based on the geometry of the stockpile, physical parameters of the material movements and emergent rules for the material movements;
predicting, by the one or more processors, the material movements exiting the stockpile, based on the material movements within the stockpile;
predicting, by the one or more processors using a concentrator transit model, the material movements across a comminution process in a concentrator, based on the material movements exiting the stockpile; and
optimizing, by the one or more processors, mining operations based on the material movements through the comminution process.

20. A system comprising:
one or more processors; and
one or more tangible, non-transitory memories configured to communicate with the one or more processors,
the one or more tangible, non-transitory memories having instructions stored thereon that, in response to execution by the one or more processors, cause the one or more processors to perform operations comprising:
determining, by the one or more processors, a geometry of a stockpile based on the haulage data, engineering drawings and material characteristics;
predicting, by the one or more processors using an algorithm implementing a cellular automaton, material movements within the stockpile, based on the geometry of the stockpile, physical parameters of the material movements and emergent rules for the material movements;
predicting, by the one or more processors, the material movements exiting the stockpile, based on the material movements within the stockpile;
predicting, by the one or more processors using a concentrator transit model, the material movements across a comminution process in a concentrator, based on the material movements exiting the stockpile; and
optimizing, by the one or more processors, mining operations based on the material movements through the comminution process.
